(19) United States
(12) Patent Application Publication
(10) Pub. No.: US 2025/0266330 A1
(43) Pub. Date: Aug. 21, 2025

(54) SEMICONDUCTOR DEVICE

(71) Applicant: Rohm Co., Ltd., Kyoto-shi (JP)

(72) Inventors: Akinori NII, Kyoto-shi (JP); Kenji FUJII, Kyoto-shi (JP)

(21) Appl. No.: 19/198,750

(22) Filed: May 5, 2025

Related U.S. Application Data
(63) Continuation of application No. PCT/JP2023/038914, filed on Oct. 27, 2023.

(30) Foreign Application Priority Data
Nov. 8, 2022 (JP) 2022-178744
Nov. 8, 2022 (JP) 2022-178745

(51) Int. Cl. H01L 23/495; H01L 23/00; H01L 23/31

(52) U.S. Cl. CPC H01L 23/49541; H01L 23/3121; H01L 23/49548; H01L 24/16; H01L 2224/16245

(57) ABSTRACT

A semiconductor device includes a semiconductor element, a plurality of leads, and a sealing resin covering the semiconductor element and the plurality of leads. The sealing resin includes a resin reverse surface and first to third resin side surfaces. The plurality of leads include a plurality of first leads aligned in the first direction. Each of the first leads includes a first mounting surface exposed from the resin reverse surface. The first mounting surface reaches the first resin side surface, and is spaced apart from the second resin side surface and the third resin side surface. The first mounting surface has a first length in the second direction. The first length of each of the first leads located at opposite ends in the first direction is longer than the first length of any of a rest of the first leads.

### TECHNICAL FIELD

The present disclosure relates to a semiconductor device.

### BACKGROUND ART

JP-A-2022-87155 discloses an example of a conventional semiconductor device. The semiconductor device disclosed in JP-A-2022-87155 includes a semiconductor element, a plurality of leads, and a sealing resin. Each of the leads has a mounting surface exposed from a reverse surface of the sealing resin. The mounting surfaces are aligned along side surfaces of the sealing resin.

### BRIEF DESCRIPTION OF THE DRAWINGS

FIG. 1 is a perspective view showing a semiconductor device according to a first embodiment of the present disclosure.

FIG. 2 is a perspective view showing the semiconductor device according to the first embodiment of the present disclosure.

FIG. 3 is a partial perspective view showing the semiconductor device according to the first embodiment of the present disclosure.

FIG. 4 is a plan view showing the semiconductor device according to the first embodiment of the present disclosure.

FIG. 5 is a bottom view showing the semiconductor device according to the first embodiment of the present disclosure.

FIG. 6 is a front view showing the semiconductor device according to the first embodiment of the present disclosure.

FIG. 7 is a rear view showing the semiconductor device according to the first embodiment of the present disclosure.

FIG. 8 is a right-side view showing the semiconductor device according to the first embodiment of the present disclosure.

FIG. 9 is a left-side view showing the semiconductor device according to the first embodiment of the present disclosure.

FIG. 10 is a cross-sectional view along line X-X in FIG. 4.

FIG. 11 is a cross-sectional view along line XI-XI in FIG. 4.

FIG. 12 is a cross-sectional view along line XII-XII in FIG. 4.

FIG. 13 is a partially enlarged plan view showing the semiconductor device according to the first embodiment of the present disclosure.

FIG. 14 is a partially enlarged plan view showing the semiconductor device according to the first embodiment of the present disclosure.

FIG. 15 is a partially enlarged plan view showing the semiconductor device according to the first embodiment of the present disclosure.

FIG. 16 is a partially enlarged plan view showing the semiconductor device according to the first embodiment of the present disclosure.

FIG. 17 is a bottom view showing a first variation of the semiconductor device according to the first embodiment of the present disclosure.

FIG. 18 is a bottom view showing a semiconductor device according to a second embodiment of the present disclosure.

FIG. 19 is a bottom view showing a semiconductor device according to a third embodiment of the present disclosure.

FIG. 20 is a bottom view showing a semiconductor device according to a fourth embodiment of the present disclosure.

FIG. 21 is a partially enlarged plan view showing a second variation of the semiconductor device according to the first embodiment of the present disclosure.

FIG. 22 is a partially enlarged plan view showing a third variation of the semiconductor device according to the first embodiment of the present disclosure.

FIG. 23 is a plan view showing a semiconductor device according to a fifth embodiment of the present disclosure.

### DETAILED DESCRIPTION OF EMBODIMENTS

The following describes preferred embodiments of the present disclosure in detail with reference to the drawings.

The terms such as “first”, “second” and “third” in the present disclosure are used merely for identification, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a part of an object B”. Further, the phrase “a plane A faces (a first side or a second side) in a direction B” is not limited to the case where the angle of the plane A with respect to the direction B is 90°, but also includes the case where the plane A is inclined to the direction B.

### First Embodiment

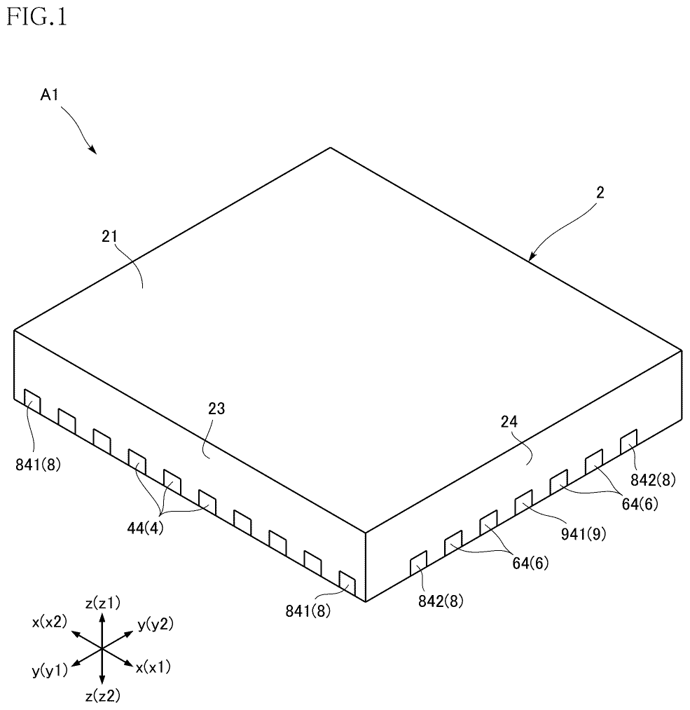

FIGS. 1 to 16 show a semiconductor device according to a first embodiment of the present disclosure. A semiconductor device A1 of the present embodiment includes a semiconductor element 1, a sealing resin 2, and a plurality of leads 4 to 9. The semiconductor device A1 is provided in a quad flat no-lead package (QFN package), but the basic configuration of the semiconductor device of the present disclosure is not particularly limited.

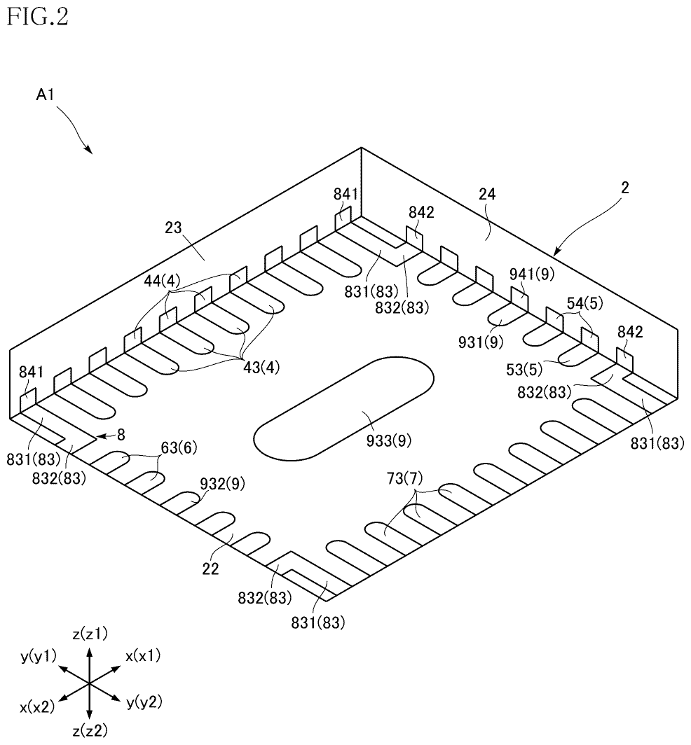

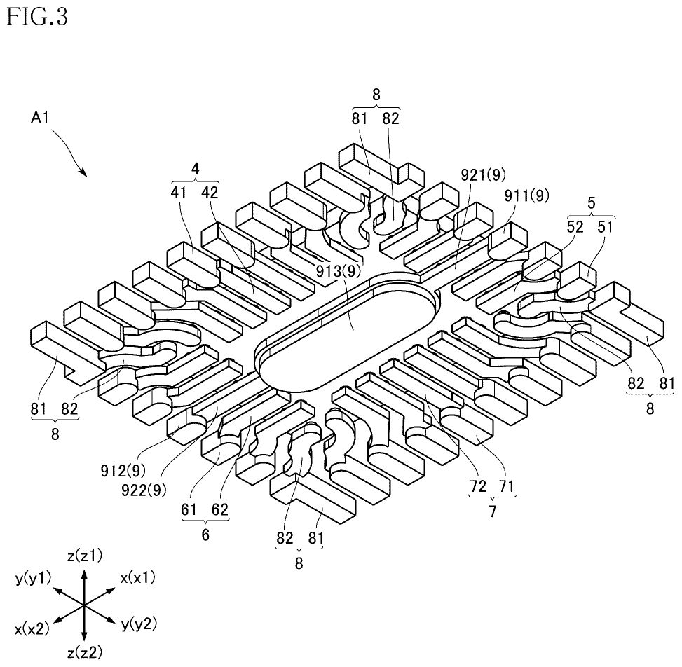

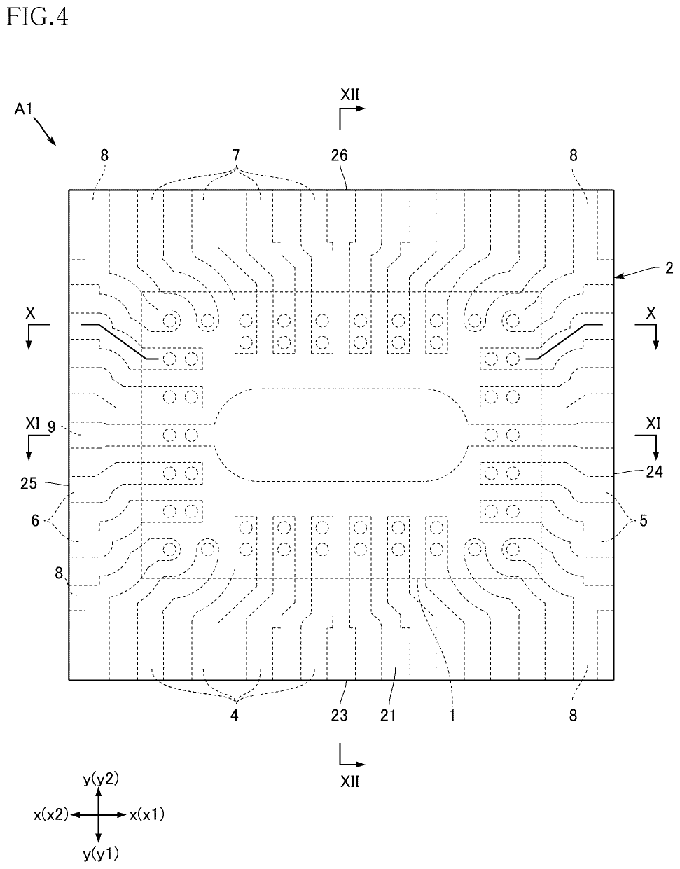

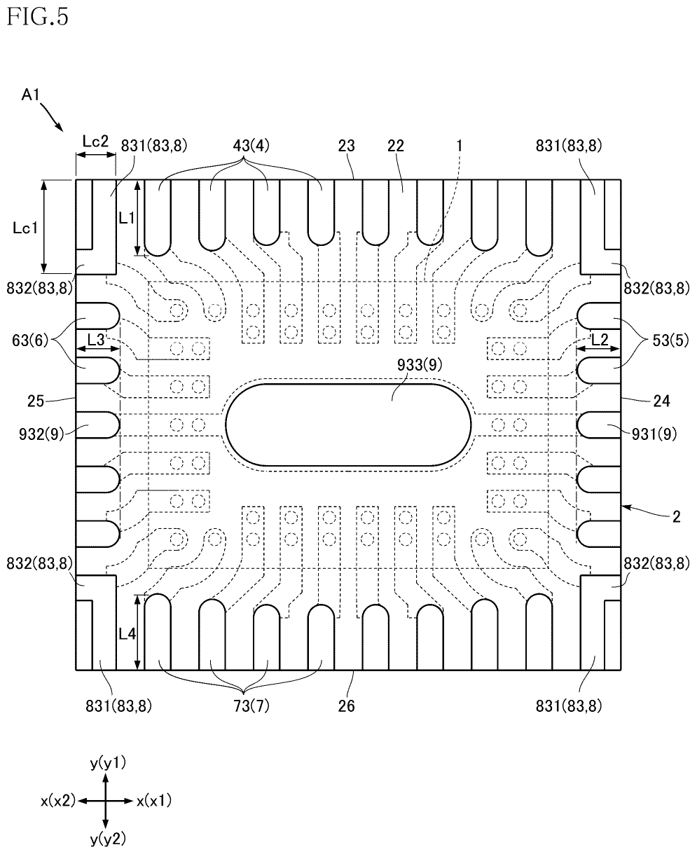

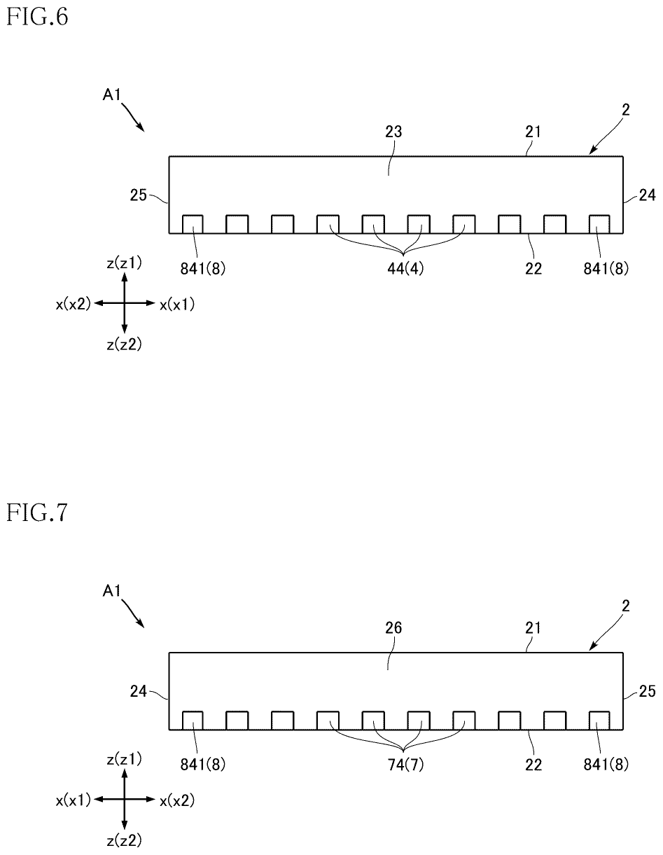

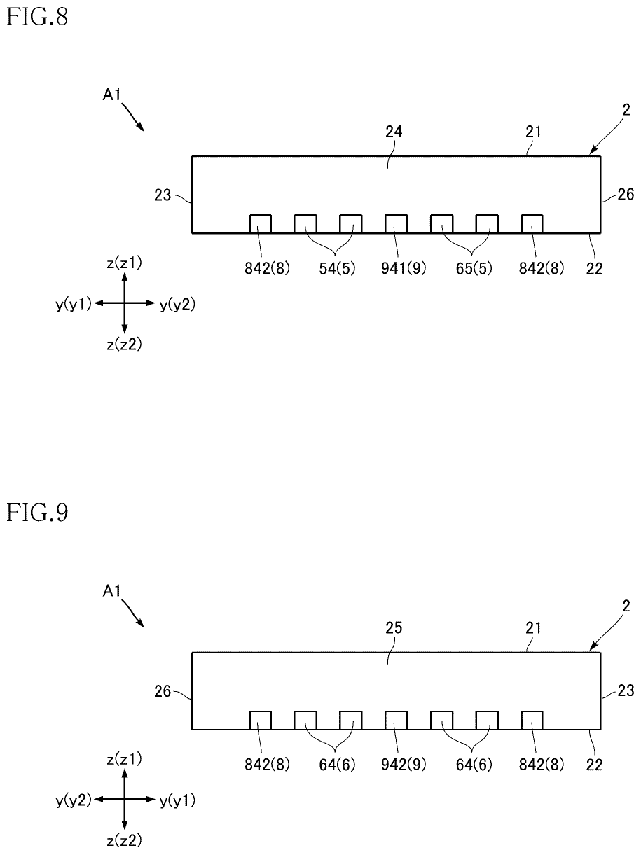

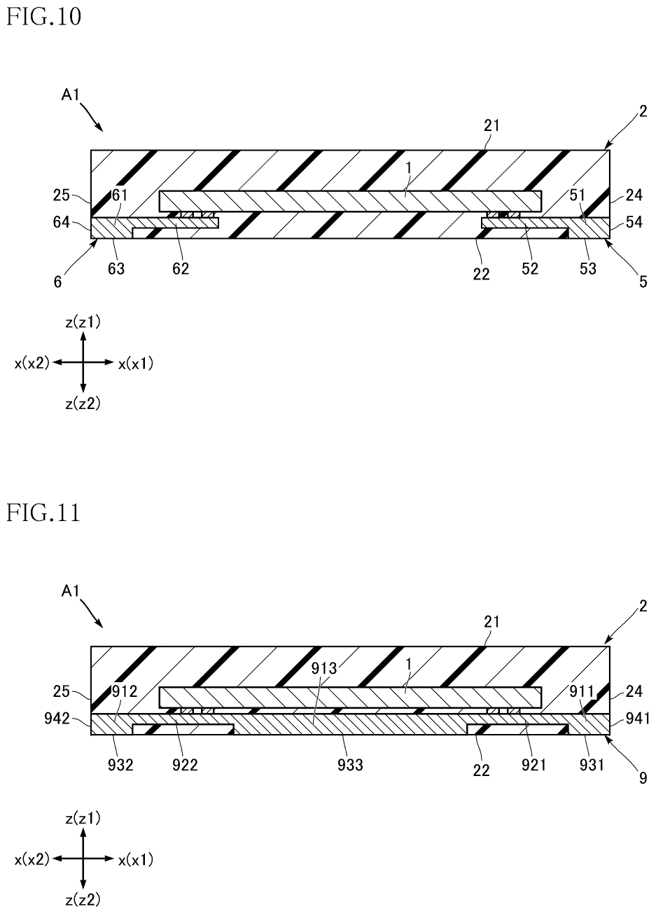

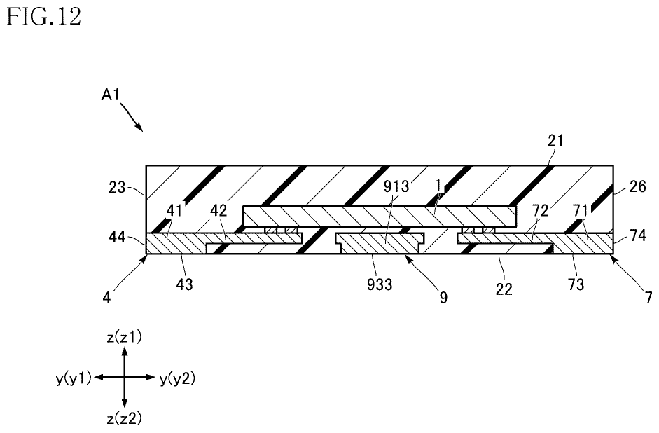

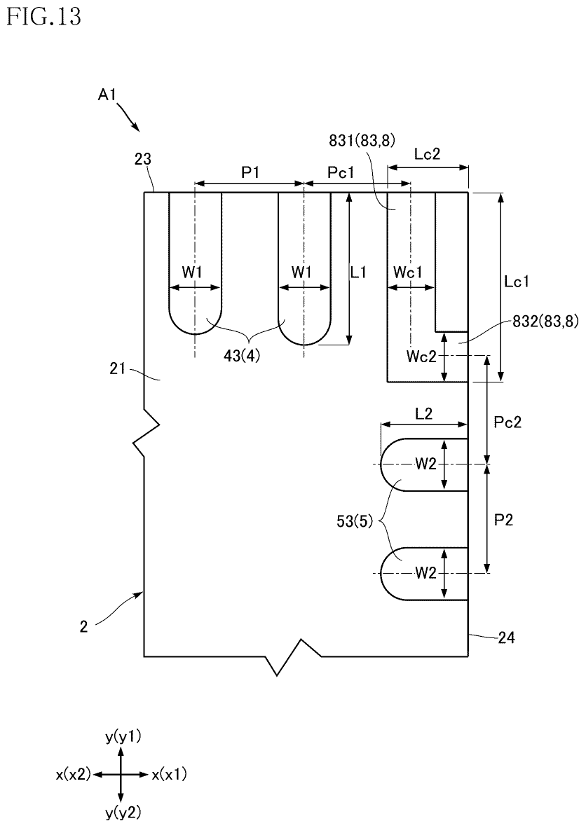

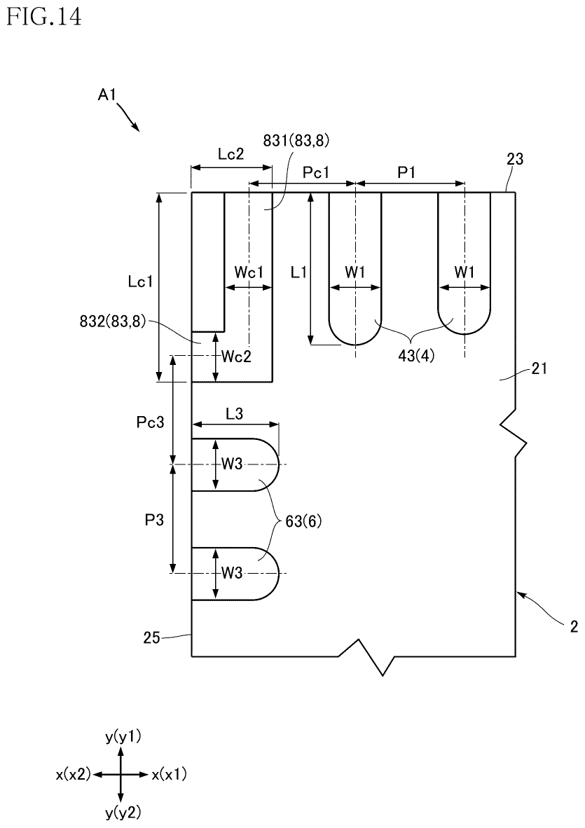

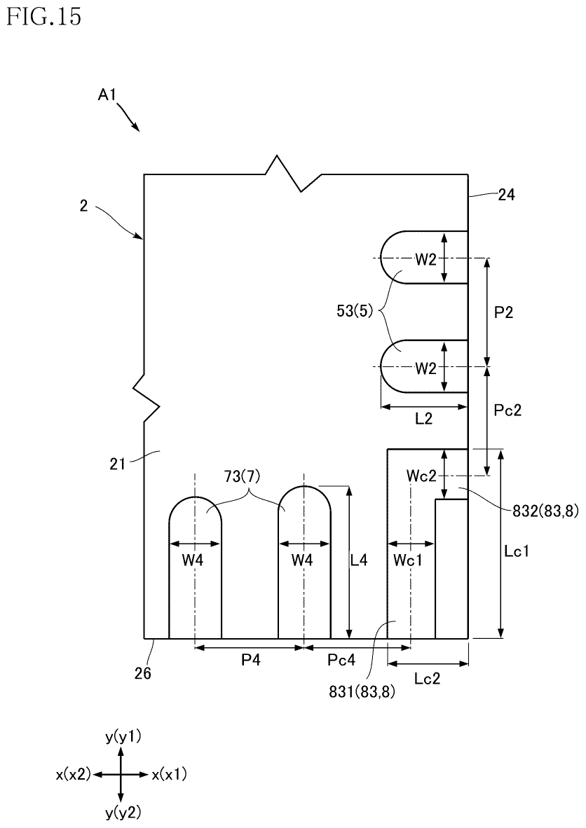

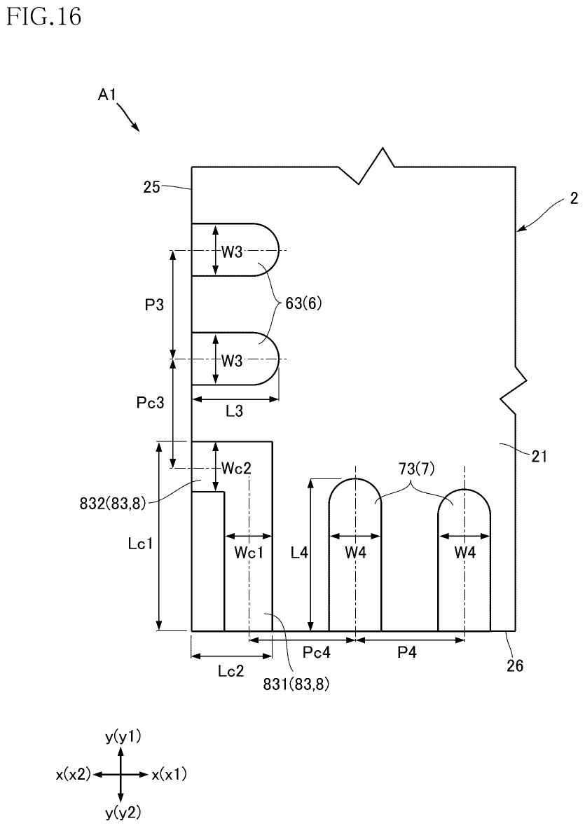

FIG. 1 is a perspective view showing the semiconductor device A1. FIG. 2 is a perspective view showing the semiconductor device A1. FIG. 3 is a partial perspective view showing the semiconductor device A1. FIG. 4 is a plan view showing the semiconductor device A1. FIG. 5 is a bottom view showing the semiconductor device A1. FIG. 6 is a front view showing the semiconductor device A1. FIG. 7 is a rear view showing the semiconductor device A1. FIG. 8 is a right-side view showing the semiconductor device A1. FIG. 9 is a left-side view showing the semiconductor device A1. FIG. 10 is a cross-sectional view along line X-X in FIG. 4. FIG. 11 is a cross-sectional view along line XI-XI in FIG. 4. FIG. 12 is a cross-sectional view along line XII-XII in FIG. 4. FIG. 13 is a partially enlarged plan view showing the semiconductor device A1. FIG. 14 is a partially enlarged plan view showing the semiconductor device A1. FIG. 15 is a partially enlarged plan view showing the semiconductor device A1. FIG. 16 is a partially enlarged plan view showing the semiconductor device A1.

In these figures, a thickness direction z is an example of a thickness direction in the present disclosure. A first direction x refers to a direction perpendicular to the thickness direction z. A second direction y refers to the direction perpendicular to the thickness direction z and the first direction x.

### Semiconductor Element 1:

The semiconductor element 1 performs main electrical functions of the semiconductor device A1 when the semiconductor device A1 is mounted on a circuit board or the like to form a part of an electrical circuit. The semiconductor element 1 is not particularly limited to a specific configuration, and may be a large scale integration (LSI) circuit or an integrated circuit (IC), for example. The semiconductor element 1 of the present embodiment has a rectangular shape having two sides extending in the first direction x and two sides extending in the second direction y as viewed in the thickness direction z.

### Sealing Resin 2:

The sealing resin 2 covers the semiconductor element 1 and a part of each of the leads 4 to 9. The sealing resin 2 is not particularly limited to a specific configuration, and may be made of a material containing epoxy resin. As shown in FIGS. 1, 2, and 4 to 16, the sealing resin 2 of the present embodiment has a resin obverse surface 21, a resin reverse surface 22, a first resin side surface 23, a second resin side surface 24, a third resin side surface 25, and a fourth resin side surface 26.

The resin obverse surface 21 faces a z1 side in the thickness direction z. In the illustrated example, the resin obverse surface 21 is a flat surface having a rectangular shape. The resin reverse surface 22 faces a z2 side in the thickness direction z. In the illustrated example, the resin reverse surface 22 is a flat surface having a rectangular shape. The first resin side surface 23 is a surface along the first direction x and the thickness direction z, and faces a y1 side in the second direction y. The second resin side surface 24 is a surface along the second direction y and the thickness direction z, and faces an x1 side in the first direction x. The third resin side surface 25 is a surface along the second direction y and the thickness direction z, and faces an x2 side in the first direction x. The fourth resin side surface 26 is a surface along the first direction x and the thickness direction z, and faces a y2 side in the second direction y.

In the present embodiment, the length of each of the first resin side surface 23 and the fourth resin side surface 26 in the first direction x is longer than the length of each of the second resin side surface 24 and the third resin side surface 25 in the second direction y.

The leads 4 to 9 have functions of supporting the semiconductor element 1 and forming conductive paths to the semiconductor element 1, for example. The specific configuration of the leads 4 to 9 is not particularly limited. The leads 4 to 9 are made of a material containing any of copper (Cu), nickel (Ni), iron (Fe), and alloys of these metals, for example. In the following description, the leads 4 to 9 are distinguished as a plurality of first leads 4, a plurality of second leads 5, a plurality of third leads 6, a plurality of fourth leads 7, a plurality of corner leads 8, and a center lead 9.

### First Leads 4:

As shown in FIGS. 1 to 6, and 12 to 14, the first leads 4 are aligned in the first direction x. Each of the first leads 4 has a first thick portion 41, a first thin portion 42, a first mounting surface 43, and a first end surface 44.

The first thick portion 41 is thicker than the other portion (the first thin portion 42) of the first lead 4 in the thickness direction z. The first thick portion 41 has the first mounting surface 43 and the first end surface 44. The first thin portion 42 is thinner than the other portion (the first thick portion 41) of the first lead 4 in the thickness direction z, and is spaced apart from the resin reverse surface 22 to the z1 side in the thickness direction z. In the present embodiment, the semiconductor element 1 is mounted on the first thin portion 42. The shape of the first thin portion 42 as viewed in the thickness direction z is appropriately designed according to, for example, the position at which the semiconductor element 1 is mounted.

The first mounting surface 43 faces the z2 side in the thickness direction z, and is exposed from the resin reverse surface 22 of the sealing resin 2. In the illustrated example, the first mounting surface 43 has a shape that extends in the second direction y. In the illustrated example, the first mounting surface 43 is flush with the resin reverse surface 22. The first mounting surface 43 reaches the first resin side surface 23, and is spaced apart from the second resin side surface 24, the third resin side surface 25, and the fourth resin side surface 26.

The first end surface 44 faces the y1 side in the second direction y, and is exposed from the first resin side surface 23 of the sealing resin 2. In the illustrated example, the first mounting surface 43 is connected to the first end surface 44. However, there may be a recessed surface or the like interposed between the first mounting surface 43 and the first end surface 44. Each of the first mounting surface 43 and the first end surface 44 may be provided with a plating layer (not illustrated) containing tin (Sn), for example. In the illustrated example, the first end surface 44 is flush with the first resin side surface 23.

Array pitches P1 between the first mounting surfaces 43 of the first leads 4 are not particularly limited. In the illustrated example, the array pitches P1 between the first mounting surfaces 43 are constant. In addition, widths W1, which are the dimensions of the first mounting surfaces 43 in the first direction x, are not particularly limited. In the illustrated example, the widths W1 of the first mounting surfaces 43 are uniform.

First lengths L1, which are the lengths of the first leads 4 in the second direction y, are such that the first length L1 of each of the first leads 4 located at opposite ends in the first direction x is longer than the first length L1 of any of the rest of the first leads 4. In other words, the first length L1 of each of the first leads 4 flanked by the two first leads 4 located at opposite ends in the first direction x is shorter than the first length L1 of each of the first leads 4 located at opposite ends in the first direction x.

In the illustrated example, the first lengths L1 of the first leads 4 are such that the first length L1 of a first lead 4 located more outward in the first direction x is longer than the first length L1 of a first lead 4 located closer to the center in the first direction x. That is, in a comparison between the first lengths L1 of two first leads 4 adjacent to each other, the first length L1 of the first lead 4 located outward in the first direction x is longer than the first length L1 of the first lead 4 located inward in the first direction x.

### Second Leads 5:

As shown in FIGS. 2 to 5, 8, 10, 13, and 15, the second leads 5 are aligned in the second direction y. Each of the second leads 5 has a second thick portion 51, a second thin portion 52, a second mounting surface 53, and a second end surface 54.

The second thick portion 51 is thicker than the other portion (the second thin portion 52) of the second lead 5 in the thickness direction z. The second thick portion 51 has the second mounting surface 53 and the second end surface 54. The second thin portion 52 is thinner than the other portion (the second thick portion 51) of the second lead 5 in the thickness direction z, and is spaced apart from the resin reverse surface 22 to the z1 side in the thickness direction z. In the present embodiment, the semiconductor element 1 is mounted on the second thin portion 52. The shape of the second thin portion 52 as viewed in the thickness direction z is appropriately designed according to, for example, the position at which the semiconductor element 1 is mounted.

The second mounting surface 53 faces the z2 side in the thickness direction z, and is exposed from the resin reverse surface 22 of the sealing resin 2. In the illustrated example, the second mounting surface 53 has a shape that extends in the first direction x. In the illustrated example, the second mounting surface 53 is flush with the resin reverse surface 22. The second mounting surface 53 reaches the second resin side surface 24, and is spaced apart from the first resin side surface 23, the fourth resin side surface 26, and the third resin side surface 25.

The second end surface 54 faces the x1 side in the first direction x, and is exposed from the second resin side surface 24 of the sealing resin 2. In the illustrated example, the second mounting surface 53 is connected to the second end surface 54. However, there may be a recessed surface or the like interposed between the second mounting surface 53 and the second end surface 54. Each of the second mounting surface 53 and the second end surface 54 may be provided with a plating layer (not illustrated) containing tin (Sn), for example. In the illustrated example, the second end surface 54 is flush with the second resin side surface 24.

Array pitches P2 between the second mounting surfaces 53 of the second leads 5 are not particularly limited. In the illustrated example, a pair of second leads 5 are disposed on one side of the center lead 9 in the second direction y and another pair of second leads (5) are disposed on the other side of the center lead 9 in the second direction y. The array pitch P2 between the two second mounting surfaces 53 on the y1 side in the second direction y is the same as the array pitch P2 between the two second mounting surfaces 53 on the y2 side in the second direction y. In addition, widths W2, which are the dimensions of the second mounting surfaces 53 in the second direction y, are not particularly limited. In the illustrated example, the widths W2 of the second mounting surfaces 53 are uniform.

Second lengths L2, which are the lengths of the second leads 5 in the first direction x, are not particularly limited, and may be uniform in the present embodiment. In the illustrated example, the second length L2 of each second lead 5 is shorter than the first length L1 of any of the first leads 4.

### Third Leads 6:

As shown in FIGS. 2 to 5, 8, 10, 13, and 15, the third leads 6 are aligned in the second direction y. Each of the third leads 6 has a third thick portion 61, a third thin portion 62, a third mounting surface 63, and a third end surface 64.

The third thick portion 61 is thicker than the other portion (the third thin portion 62) of the third lead 6 in the thickness direction z. The third thick portion 61 has the third mounting surface 63 and the third end surface 64. The third thin portion 62 is thinner than the other portion (the third thick portion 61) of the third lead 6 in the thickness direction z, and is spaced apart from the resin reverse surface 22 to the z1 side in the thickness direction z. In the present embodiment, the semiconductor element 1 is mounted on the third thin portion 62. The shape of the third thin portion 62 as viewed in the thickness direction z is appropriately designed according to, for example, the position at which the semiconductor element 1 is mounted.

The third mounting surface 63 faces the z2 side in the thickness direction z, and is exposed from the resin reverse surface 22 of the sealing resin 2. In the illustrated example, the third mounting surface 63 has a shape that extends in the first direction x. In the illustrated example, the third mounting surface 63 is flush with the resin reverse surface 22. The third mounting surface 63 reaches the third resin side surface 25, and is spaced apart from the first resin side surface 23, the fourth resin side surface 26, and the second resin side surface 24.

The third end surface 64 faces the x2 side in the first direction x, and is exposed from the third resin side surface 25 of the sealing resin 2. In the illustrated example, the third mounting surface 63 is connected to the third end surface 64. However, there may be a recessed surface or the like interposed between the third mounting surface 63 and the third end surface 64. Each of the third mounting surface 63 and the third end surface 64 may be provided with a plating layer (not illustrated) containing tin (Sn), for example. In the illustrated example, the third end surface 64 is flush with the third resin side surface 25.

Array pitches P3 between the third mounting surfaces 63 of the third leads 6 are not particularly limited. In the illustrated example, two third leads 6 are disposed on one side of the center lead 9 in the second direction y and another two third leads 6 are disposed on the other side of the center lead 9 in the second direction y. The array pitch P3 between the two third mounting surfaces 63 on the y1 side in the second direction y is the same as the array pitch P3 between the two third mounting surfaces 63 on the y2 side in the second direction y. In addition, widths W3, which are the dimensions of the third mounting surfaces 63 in the second direction y, are not particularly limited. In the illustrated example, the widths W3 of the third mounting surfaces 63 are uniform.

Third lengths L3, which are the lengths of the third leads 6 in the first direction x, are not particularly limited, and may be uniform in the present embodiment. In the illustrated example, the third length L3 of each third lead 6 is shorter than the first length L1 of any of the first leads 4.

### Fourth Leads 7:

As shown in FIGS. 2 to 5, 7, 12, 15, and 16, the fourth leads 7 are aligned in the first direction x. Each of the fourth leads 7 has a fourth thick portion 71, a fourth thin portion 72, a fourth mounting surface 73, and a fourth end surface 74.

The fourth thick portion 71 is thicker than the other portion (the fourth thin portion 72) of the fourth lead 7 in the thickness direction z. The fourth thick portion 71 has the fourth mounting surface 73 and the fourth end surface 74. The fourth thin portion 72 is thinner than the other portion (the fourth thick portion 71) of the fourth lead 7 in the thickness direction z, and is spaced apart from the resin reverse surface 22 to the z1 side in the thickness direction z. In the present embodiment, the semiconductor element 1 is mounted on the fourth thin portion 72. The shape of the fourth thin portion 72 as viewed in the thickness direction z is appropriately designed according to, for example, the position at which the semiconductor element 1 is mounted.

The fourth mounting surface 73 faces the z2 side in the thickness direction z, and is exposed from the resin reverse surface 22 of the sealing resin 2. In the illustrated example, the fourth mounting surface 73 has a shape that extends in the second direction y. In the illustrated example, the fourth mounting surface 73 is flush with the resin reverse surface 22. The fourth mounting surface 73 reaches the fourth resin side surface 26, and is spaced apart from the second resin side surface 24, the third resin side surface 25, and the first resin side surface 23.

The fourth end surface 74 faces the y2 side in the second direction y, and is exposed from the fourth resin side surface 26 of the sealing resin 2. In the illustrated example, the fourth mounting surface 73 is connected to the fourth end surface 74. However, there may be a recessed surface or the like interposed between the fourth mounting surface 73 and the fourth end surface 74. Each of the fourth mounting surface 73 and the fourth end surface 74 may be provided with a plating layer (not illustrated) containing tin (Sn), for example. In the illustrated example, the fourth end surface 74 is flush with the fourth resin side surface 26.

Array pitches P4 between the fourth mounting surfaces 73 of the fourth leads 7 are not particularly limited. In the illustrated example, the array pitches P4 between the fourth mounting surfaces 73 are constant. In addition, widths W4, which are the dimensions of the fourth mounting surfaces 73 in the first direction x, are not particularly limited. In the illustrated example, the widths W4 of the fourth mounting surfaces 73 are uniform.

Fourth lengths L4, which are the lengths of the fourth leads 7 in the second direction y, are such that the fourth length L4 of each of the fourth leads 7 located at opposite ends in the first direction x is longer than the fourth length L4 of any of the rest of the fourth leads 7. In other words, the fourth length L4 of each of the fourth leads 7 flanked by the two fourth leads 7 located at opposite ends in the first direction x is shorter than the fourth length L4 of each of the fourth leads 7 located at opposite ends in the first direction x.

In the illustrated example, the fourth lengths L4 of the fourth leads 7 are such that the fourth length L4 of a fourth lead 7 located more outward in the first direction x is longer than the fourth length L4 of a fourth lead 7 located closer to the center in the first direction x. That is, in a comparison between the fourth lengths L4 of two fourth leads 7 adjacent to each other, the fourth length L4 of the fourth lead 7 located outward in the first direction x is longer than the fourth length L4 of the fourth lead 7 located inward in the first direction x.

In the illustrated example, the plurality of first leads 4 and the plurality of fourth leads 7 include a first lead 4 and a fourth lead 7 that are located at the same position in the first direction x, and the first length L1 of the first lead 4 is equal to the fourth length L4 of the fourth lead 7.

### Corner Leads 8:

As shown in FIGS. 1 to 9, and 13 to 16, the corner leads 8 are disposed at the positions near the four corners of the sealing resin 2 as viewed in the thickness direction z. Two corner leads 8 flank the first leads 4 in the first direction x. The other two corner leads 8 flank the fourth leads 7 in the first direction x.

Each of the corner leads 8 has a corner thick portion 81, a corner thin portion 82, a corner mounting surface 83, a first corner end surface 841, and a second corner end surface 842.

The corner thick portion 81 is thicker than the other portion (the corner thin portion 82) of the corner lead 8 in the thickness direction z. The corner thick portion 81 has the corner mounting surface 83, the first corner end surface 841, and the second corner end surface 842. The corner thin portion 82 is thinner than the other portion (the corner thick portion 81) of the corner lead 8 in the thickness direction z, and is spaced apart from the resin reverse surface 22 to the z1 side in the thickness direction z. In the present embodiment, the semiconductor element 1 is mounted on the corner thin portion 82. The shape of the corner thin portion 82 as viewed in the thickness direction z is appropriately designed according to, for example, the position at which the semiconductor element 1 is mounted.

The corner mounting surface 83 faces the z2 side in the thickness direction z, and is exposed from the resin reverse surface 22 of the sealing resin 2. In the present embodiment, the corner mounting surface 83 has a first portion 831 and a second portion 832. The first portion 831 reaches the first resin side surface 23 or the fourth resin side surface 26, and is spaced apart from the second resin side surface 24 and the third resin side surface 25. The second portion 832 reaches the second resin side surface 24 or the third resin side surface 25, and is spaced apart from the first resin side surface 23 and the fourth resin side surface 26. The first portion 831 and the second portion 832 are connected to each other at their respective ends. In the illustrated example, the corner mounting surface 83 has an L-shape as viewed in the thickness direction z. In the illustrated example, a length Lc1, which is the length of the corner mounting surface 83 in the second direction y, is longer than a length Lc2, which is the length of the corner mounting surface 83 in the first direction x. Note that the shape and size of the corner mounting surface 83 are not particularly limited.

The first corner end surface 841 faces in the second direction y, and is exposed from the first resin side surface 23 or the fourth resin side surface 26. In the illustrated example, the first corner end surface 841 is flush with the first resin side surface 23 or the fourth resin side surface 26. The second corner end surface 842 faces in the first direction x, and is exposed from the second resin side surface 24 or the third resin side surface 25. In the illustrated example, the second corner end surface 842 is flush with the second resin side surface 24 or the third resin side surface 25.

In the corner lead 8 shown in FIG. 13, the length Lc1 of the corner mounting surface 83 in the second direction y is longer than the first length L1 of each first lead 4. The length Lc2 of the corner mounting surface 83 in the first direction x is equal to the second length L2 of each second lead 5.

In the corner lead 8 shown in FIG. 13, an array pitch Pc1 between the first mounting surface 43 of the first lead 4 closest to the x1 side in the first direction x and the first portion 831 is equal to the array pitch P1 between the first mounting surfaces 43 of the first leads 4. In addition, an array pitch Pc2 between the second mounting surface 53 of the second lead 5 closest to the y1 side in the second direction y and the second portion 832 is equal to the array pitch P2 between the second mounting surfaces 53 of the second leads 5.

In the corner lead 8 shown in FIG. 14, the length Lc1 of the corner mounting surface 83 in the second direction y is longer than the first length L1 of each first lead 4. The length Lc2 of the corner mounting surface 83 in the first direction x is equal to the third length L3 of each third lead 6.

In the corner lead 8 shown in FIG. 14, the array pitch Pc1 between the first mounting surface 43 of the first lead 4 closest to the x2 side in the first direction x and the first portion 831 is equal to the array pitch P1 between the first mounting surfaces 43 of the first leads 4. In addition, an array pitch Pc3 between the third mounting surface 63 of the third lead 6 closest to the y1 side in the second direction y and the second portion 832 is equal to the array pitch P3 between the third mounting surfaces 63 of the third leads 6.

In the corner lead 8 shown in FIG. 15, the length Lc1 of the corner mounting surface 83 in the second direction y is longer than the fourth length L4 of each fourth lead 7. The length Lc2 of the corner mounting surface 83 in the first direction x is equal to the second length L2 of each second lead 5.

In the corner lead 8 shown in FIG. 15, an array pitch Pc4 between the fourth mounting surface 73 of the fourth lead 7 closest to the x1 side in the first direction x and the first portion 831 is equal to the array pitch P4 between the fourth mounting surfaces 73 of the fourth leads 7. In addition, the array pitch Pc2 between the second mounting surface 53 of the second lead 5 closest to the y2 side in the second direction y and the second portion 832 is equal to the array pitch P2 between the second mounting surfaces 53 of the second leads 5.

In the corner lead 8 shown in FIG. 16, the length Lc1 of the corner mounting surface 83 in the second direction y is longer than the fourth length L4 of each fourth lead 7. The length Lc2 of the corner mounting surface 83 in the first direction x is equal to the third length L3 of each third lead 6.

In the corner lead 8 shown in FIG. 16, the array pitch Pc4 between the fourth mounting surface 73 of the fourth lead 7 closest to the x2 side in the first direction x and the first portion 831 is equal to the array pitch P4 between the fourth mounting surfaces 73 of the fourth leads 7. In addition, the array pitch Pc3 between the third mounting surface 63 of the third lead 6 closest to the y2 side in the second direction y and the second portion 832 is equal to the array pitch P3 between the third mounting surfaces 63 of the third leads 6.

### Center Lead 9:

As shown in FIGS. 1 to 5, 8, 9, 11, and 12, the center lead 9 is disposed between the second leads 5 or between the third leads 6 in the second direction y. In the illustrated example, the center lead 9 overlaps with the center of the semiconductor device A1 (the sealing resin 2) in the second direction y. In the illustrated example, the center lead 9 has a center thick portion 911, a center thick portion 912, a center thick portion 913, a center thin portion 921, a center thin portion 922, a center mounting surface 931, a center mounting surface 932, a center mounting surface 933, a center end surface 941, and a center end surface 942.

The center mounting surface 931, the center mounting surface 932, and the center mounting surface 933 are thicker than the other portions (the center thin portion 921 and the center thin portion 922) of the center lead 9 in the thickness direction z. The center thick portion 911 has the center mounting surface 931 and the center end surface 941. The center thick portion 912 has the center mounting surface 932 and the center end surface 942. The center thick portion 913 has the center mounting surface 933. The center thick portion 911 is disposed on the x1 side in the first direction x. The center thick portion 912 is disposed on the x2 side in the first direction x. The center thick portion 913 is disposed at the center in the first direction x.

The center thin portion 921 and the center thin portion 922 are thinner than the other portions (the center thick portion 911, the center thick portion 912, and the center thick portion 913) of the center lead 9 in the thickness direction z, and are spaced apart from the resin reverse surface 22 to the z1 side in the thickness direction z. In the present embodiment, the semiconductor element 1 is mounted on the center thin portion 921 and the center thin portion 922.

In the illustrated example, the length of the center mounting surface 931 in the first direction x is equal to the second length L2 of the second mounting surface 53 of each second lead 5. The length of the center mounting surface 932 in the first direction x is equal to the third length L3 of the third mounting surface 63 of each third lead 6. The array pitch between the center mounting surface 931 and a second mounting surface 53 adjacent thereto in the second direction y is equal to the array pitch P2 between the second mounting surfaces 53. The array pitch between the center mounting surface 932 and a third mounting surface 63 adjacent thereto in the second direction y is equal to the array pitch P3 between the third mounting surfaces 63.

Next, advantages of the semiconductor device A1 will be described.

When the semiconductor device A1 is mounted on a circuit board, for example, the first mounting surfaces 43 of the leads 4 are electrically bonded to the circuit board via conductive bonding members such as solder. Similarly, the mounting surfaces of the leads 5 to 9 are also electrically bonded to the circuit board via conductive bonding members. During the use of the semiconductor device A1, these conductive bonding members may be subjected to thermal stress or the like. The test conducted by the inventors has shown that, out of the conductive bonding members bonded to the first mounting surfaces 43 of the first leads 4, the conductive bonding members bonded to the first mounting surfaces 43 located at opposite ends in the first direction x tend to be susceptible to the largest thermal stress. The test has also shown that the conductive bonding members located near the four corners of the sealing resin 2 as viewed in the thickness direction z tend to be susceptible to large thermal stress.

According to the present embodiment, as shown in FIG. 5, the first lengths L1, which are the lengths of the first leads 4 in the second direction y, are such that the first length L1 of each of the first leads 4 located at opposite ends in the first direction x is longer than the first length L1 of any of the rest of the first leads 4. In other words, the first length L1 of each of the first leads 4 flanked by the two first leads 4 located at opposite ends in the first direction x is shorter than the first length L1 of each of the first leads 4 located at opposite ends in the first direction x. This configuration can suppress excessive stress on the conductive bonding members bonded to the first mounting surfaces 43 located at opposite ends in the first direction x.

In the illustrated example, the first lengths L1 of the first leads 4 are such that the first length L1 of a first lead 4 located more outward in the first direction x is longer than the first length L1 of a first lead 4 located closer to the center in the first direction x. That is, in a comparison between the first lengths L1 of two first leads 4 adjacent to each other, the first length L1 of the first lead 4 located outward in the first direction x is longer than the first length L1 of the first lead 4 located inward in the first direction x. With this configuration, the stress generated in the conductive bonding members bonded to the first mounting surfaces 43 can be reduced in a well-balanced manner.

According to the present embodiment, as shown in FIG. 5, the fourth lengths L4, which are the lengths of the fourth leads 7 in the second direction y, are such that the fourth length L4 of each of the fourth leads 7 located at opposite ends in the first direction x is longer than the fourth length L4 of any of the rest of the fourth leads 7. In other words, the fourth length L4 of each of the fourth leads 7 flanked by the two fourth leads 7 located at opposite ends in the first direction x is shorter than the fourth length L4 of each of the fourth leads 7 located at opposite ends in the first direction x. This configuration can suppress excessive stress on the conductive bonding members bonded to the fourth mounting surfaces 73 located at opposite ends in the first direction x.

In the illustrated example, the fourth lengths L4 of the fourth leads 7 are such that the fourth length L4 of a fourth lead 7 located more outward in the first direction x is longer than the fourth length L4 of a fourth lead 7 located closer to the center in the first direction x. That is, in a comparison between the fourth lengths L4 of two fourth leads 7 adjacent to each other, the fourth length L4 of the fourth lead 7 located outward in the first direction x is longer than the fourth length L4 of the fourth lead 7 located inward in the first direction x. With this configuration, the stress generated in the conductive bonding members bonded to the fourth mounting surfaces 73 can be reduced in a well-balanced manner.

Each of the corner mounting surfaces 83 has a first portion 831 and a second portion 832. The first portion 831 reaches the first resin side surface 23 or the fourth resin side surface 26, and is spaced apart from the second resin side surface 24 and the third resin side surface 25. The second portion 832 reaches the second resin side surface 24 or the third resin side surface 25, and is spaced apart from the first resin side surface 23 and the fourth resin side surface 26. The first portion 831 and the second portion 832 are connected to each other at their respective ends. Thus, the corner mounting surfaces 83 are configured to be spaced apart from the corners at each of which two of the first resin side surface 23, the second resin side surface 24, the third resin side surface 25, and the fourth resin side surface 26 are connected to each other. This makes it possible to suppress excessive stress on the conductive bonding members bonded to the corner mounting surfaces 83.

In the corner lead 8 shown in FIG. 13, an array pitch Pc1 between the first mounting surface 43 of the first lead 4 closest to the x1 side in the first direction x and the first portion 831 is equal to the array pitch P1 between the first mounting surfaces 43. This makes it possible to suppress excessive stress on one of the conductive bonding members bonded to the first mounting surfaces 43 and the first portion 831. This advantage can also be obtained by the relationship between the array pitch Pc1 and the array pitch P1 shown in FIG. 14, the relationship between the array pitch Pc4 and the array pitch P4 shown in FIG. 15, and the relationship between the array pitch Pc4 and the array pitch P4 shown in FIG. 16.

In addition, as shown in FIG. 13, the array pitch Pc2 between the second mounting surface 53 of the second lead 5 closest to the y1 side in the second direction y and the second portion 832 is equal to the array pitch P2 between the second mounting surfaces 53 of the second leads 5. This makes it possible to suppress excessive stress on one of the conductive bonding members bonded to the second mounting surfaces 53 and the second portion 832. This advantage can also be obtained by the relationship between the array pitch Pc3 and the array pitch P3 shown in FIG. 14, the relationship between the array pitch Pc2 and the array pitch P2 shown in FIG. 15, and the relationship between the array pitch Pc3 and the array pitch P3 shown in FIG. 16.

As shown in FIGS. 13 to 16, a width Wc1 of each first portion 831 is equal to the width W1 of each first mounting surface 43 or the width W4 of each fourth mounting surface 73. A width Wc2 of each second portion 832 is equal to the width W2 of each second mounting surface 53 or the width W3 of each third mounting surface 63. This makes it possible to further uniformize the stress generated in the conductive bonding members bonded to these mounting surfaces.

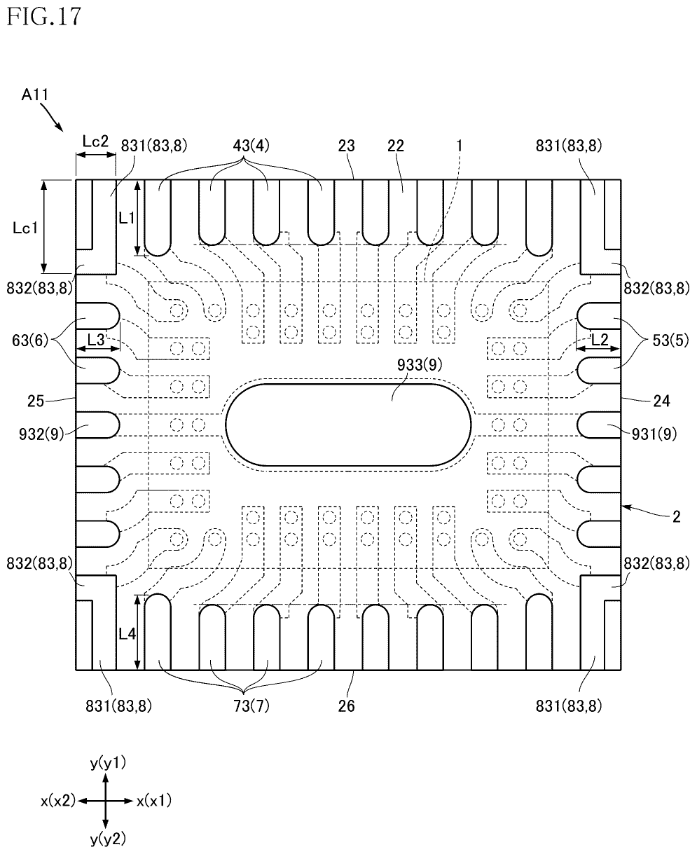

FIGS. 17 to 20 show variations and other embodiments of the present disclosure. In these figures, elements that are the same as or similar to those in the above embodiment are provided with the same reference numerals as in the above embodiment. The configurations of the elements in each variation and each embodiment can be combined as appropriate as long as the combination does not cause technical inconsistency.

### First Variation of the First Embodiment

FIG. 17 shows a first variation of the semiconductor device A1. A semiconductor device A11 of the present variation is different from the above example in the configurations of the first leads 4 and the fourth leads 7.

In the present variation, the first lengths L1 of the first leads 4 other than those of the first leads 4 located at opposite ends in the first direction x are equal. The first length L1 of each of the first leads 4 located at opposite ends in the first direction x is longer than the first length L1 of any of the rest of the first leads 4.

In the present variation, the fourth lengths L4 of the fourth leads 7 other than those of the fourth leads 7 located at opposite ends in the first direction x are equal. The fourth length L4 of each of the fourth leads 7 located at opposite ends in the first direction x is longer than the fourth length L4 of any of the rest of the fourth leads 7.

The present variation can also suppress excessive stress on the conductive bonding members used for mounting. As can be understood from the present variation, various changes can be made to the configuration where the first length L1 of each of the first leads 4 located at opposite ends in the first direction x is longer than the first length L1 of any of the rest of the first leads 4. Various changes can also be made to the configuration where the fourth length L4 of each of the fourth leads 7 located at opposite ends in the first direction x is longer than the fourth length L4 of any of the rest of the fourth leads 7.

### Second Embodiment

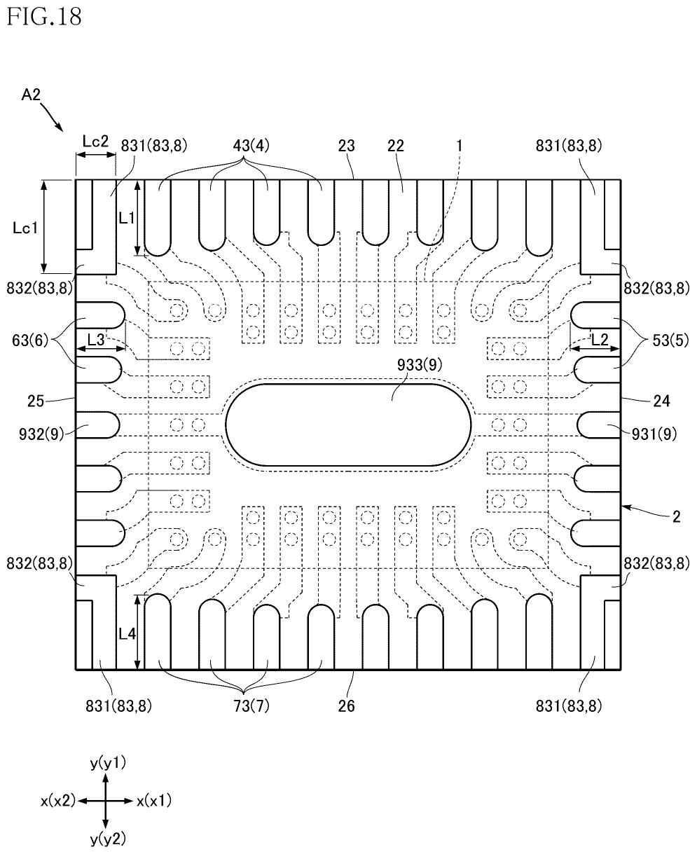

FIG. 18 shows a semiconductor device according to a second embodiment of the present disclosure. A semiconductor device A2 of the present embodiment is different from the above embodiment in the configurations of the second leads 5 and the third leads 6.

In the present embodiment, the second length L2 of each of the second leads 5 located at opposite ends in the second direction y is longer than the second length L2 of any of the rest of the second leads 5. In other words, the second length L2 of each of the second leads 5 flanked by the two second leads 5 located at opposite ends in the second direction y is shorter than the second length L2 of each of the second leads 5 located at opposite ends in the second direction y.

In the illustrated example, the second lengths L2 of the second leads 5 are such that the second length L2 of a second lead 5 located more outward in the second direction y is longer than the second length L2 of a second lead 5 located closer to the center in the second direction y. That is, in a comparison between the second lengths L2 of two second leads 5 adjacent to each other, the second length L2 of the second lead 5 located outward in the second direction y is longer than the second length L2 of the second lead 5 located inward in the second direction y.

The present embodiment can also suppress excessive stress on the conductive bonding members used for mounting. The present embodiment can more effectively suppress excessive stress on the conductive bonding members by selecting the second lengths L2 of the second leads 5 and the third lengths L3 of the third leads 6 as described above.

### Third Embodiment

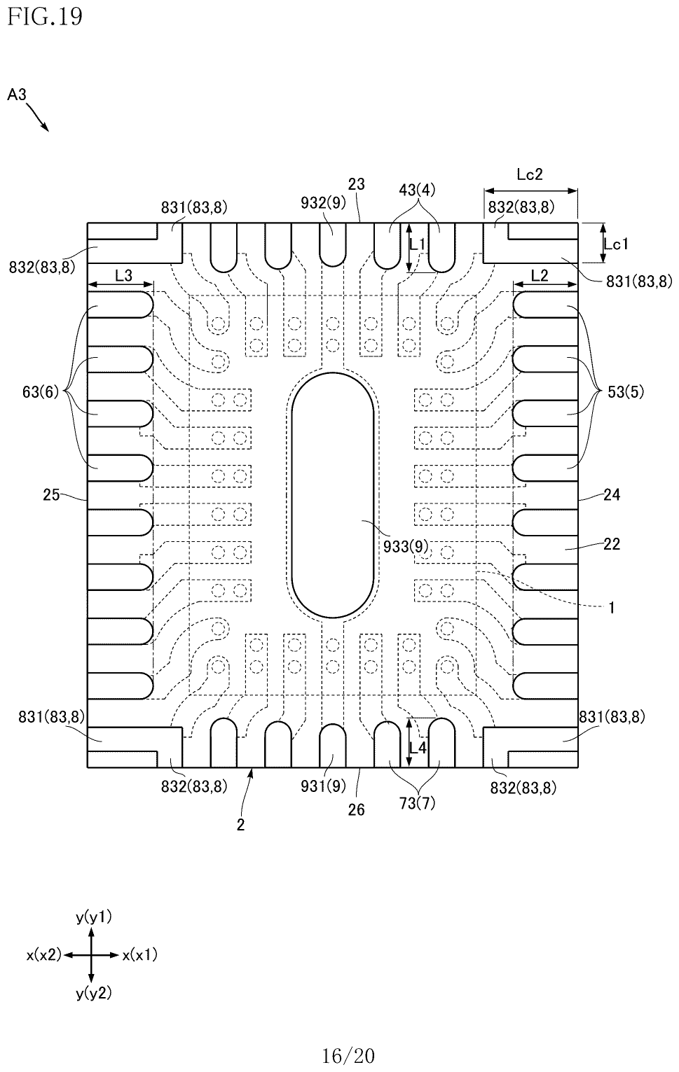

FIG. 19 shows a semiconductor device according to a third embodiment of the present disclosure. In a semiconductor device A3 of the present embodiment, the length of each of the first resin side surface 23 and the fourth resin side surface 26 in the first direction x is shorter than the length of each of the second resin side surface 24 and the third resin side surface 25 in the second direction y. In addition, the center lead 9 is disposed between the first leads 4 and the fourth leads 7 in the first direction x.

The present embodiment is similar to the above embodiments in that the first length L1 of each of the first leads 4 located at opposite ends in the first direction x is longer than the first length L1 of any of the rest of the first leads 4, and that the fourth length L4 of each of the fourth leads 7 located at opposite ends in the first direction x is longer than the fourth length L4 of any of the rest of the fourth leads 7. In other words, the semiconductor device A3 is obtained by rotating the configuration similar to the semiconductor device A1 by 90 degrees as viewed in the thickness direction z and redefining the names, the reference numerals, and so on.

The present embodiment can also suppress excessive stress on the conductive bonding members used for mounting. As can be understood from the present embodiment, when the sealing resin 2 is rectangular as viewed in the thickness direction z, the lengths of the leads located at opposite ends on the shorter sides, the longer sides, or both the shorter and longer sides of the rectangular sealing resin 2 can be made longer as appropriate.

### Fourth Embodiment

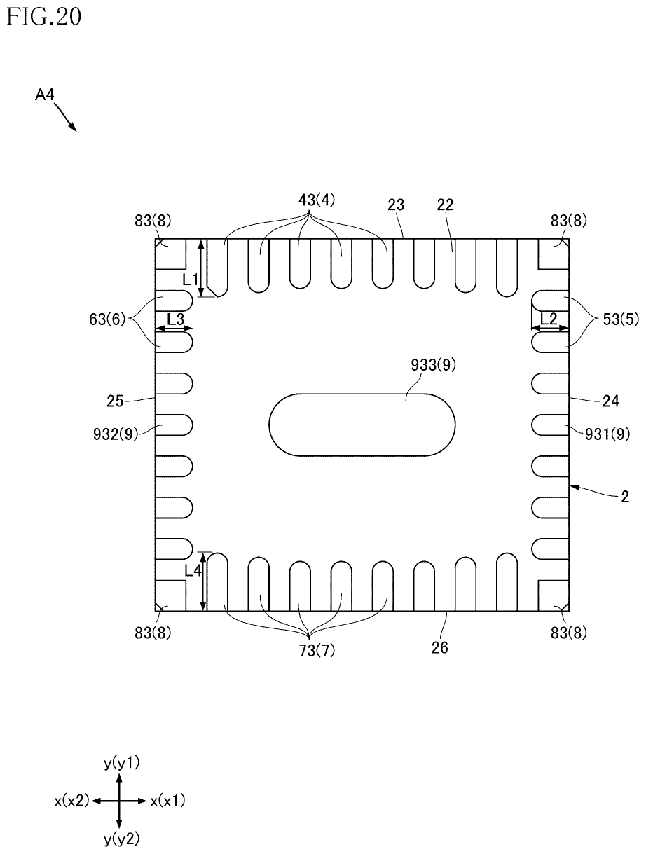

FIG. 20 shows a semiconductor device according to a fourth embodiment of the present disclosure. A semiconductor device A4 of the present embodiment is different from the above embodiments in the configuration of each corner lead 8.

In the present embodiment, the corner mounting surface 83 of each corner lead 8 has a pentagonal shape obtained by chamfering one corner of a rectangle. The dimension of the corner mounting surface 83 in the second direction y is smaller than each of the first lengths L1 and the fourth lengths L4, and the dimension of the corner mounting surface 83 in the first direction x is smaller than each of the second lengths L2 and the third lengths L3.

In the present embodiment, the second mounting surface 53 and the third mounting surface 63 closest to the y1 side in the second direction y overlap with the first mounting surfaces 43 located at opposite ends in the first direction x as viewed in the first direction x. The second mounting surface 53 and the third mounting surface 63 closest to the y2 side in the second direction y overlap with the fourth mounting surfaces 73 located at opposite ends in the first direction x as viewed in the first direction x.

The present embodiment can also suppress excessive stress on the conductive bonding members used for mounting. As can be understood from the present embodiment, the configuration of each corner lead 8 is not particularly limited and may be selected as appropriate. In another example, the semiconductor device of the present disclosure may not include the corner leads 8.

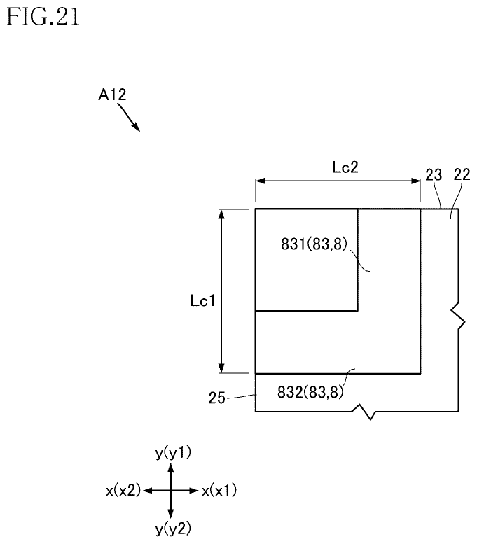

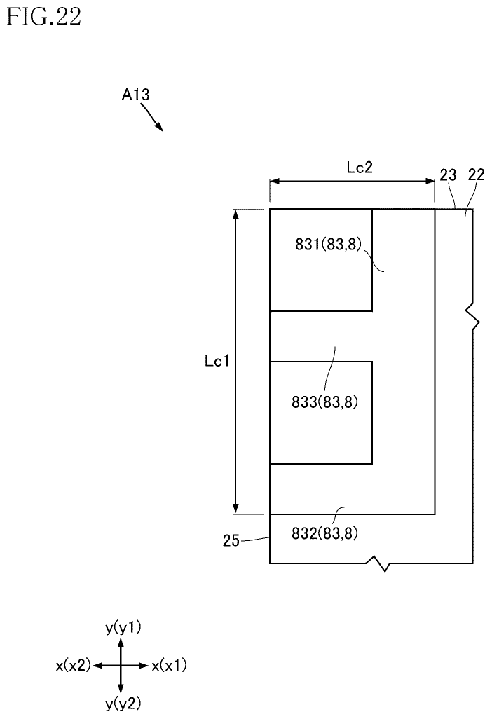

The semiconductor device of the present disclosure is not limited to the first to fourth embodiments and the variations described above. FIGS. 21 to 23 show other variations and another embodiment of the present disclosure. In these figures, elements that are the same as or similar to those in the variation and embodiments described above are provided with the same reference numerals as in the variation and embodiments described above. The configurations of the elements in each variation and each embodiment can be combined as appropriate as long as the combination does not cause technical inconsistency.

### Second Variation of the First Embodiment

FIG. 21 shows a second variation of the semiconductor device A1. A semiconductor device A12 in the present variation is different from the example described above (see FIG. 14) in the configuration of each corner lead 8.

In the present variation, the length Lc1 and the length Lc2 of each corner mounting surface 83 are equal to each other. In this case, the sealing resin 2 may have a square shape as viewed in the thickness direction z.

The present variation can also suppress excessive stress on the conductive bonding members used for mounting. As can be understood from the present variation, the specific shape, etc., of each corner mounting surface 83 is not particularly limited.

### Third Variation of the First Embodiment

FIG. 22 shows a third variation of the semiconductor device A1. A semiconductor device A13 in the present variation is different from the examples described above in the configuration of each corner lead 8.

In the present variation, each of the corner mounting surfaces 83 has a first portion 831, a second portion 832, and a third portion 833. The third portion 833 is located between the second portion 832 and either the first resin side surface 23 or the fourth resin side surface 26 in the second direction y, and reaches the first portion 831 and either the second resin side surface 24 or the third resin side surface 25. Since each corner mounting surface 83 has a first portion 831, a second portion 832, and a third portion 833, the corner mounting surface 83 has an F-shape as viewed in the thickness direction z.

In the illustrated example, the third portion 833 is located between the second portion 832 and the first resin side surface 23 in the second direction y, and reaches the first portion 831 and the third resin side surface 25. The array pitch between the second portion 832 and the third portion 833 may be the same as the array pitch P2 or the array pitch P3 in the above examples. The width of each of the second portion 832 and the third portion 833 in the second direction y may be the same as the width W2 or the width W3 in the above examples.

The present variation can also suppress excessive stress on the conductive bonding members used for mounting. As can be understood from the present variation, the specific shape, etc., of each corner mounting surface 83 is not particularly limited as long as the corner mounting surfaces 83 are spaced apart from the four corners of the sealing resin 2.

### Fifth Embodiment

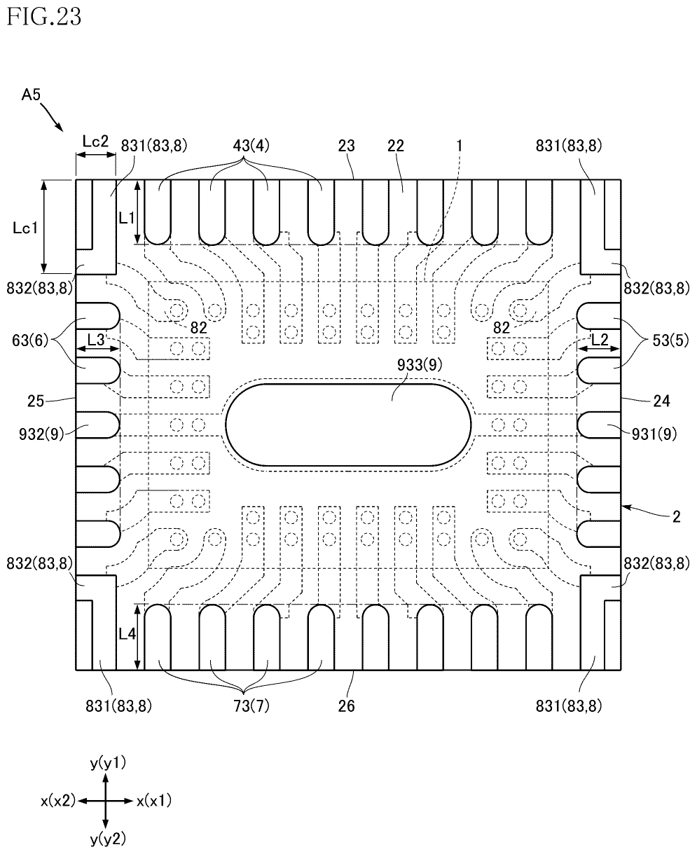

FIG. 23 shows a semiconductor device according to a fifth embodiment of the present disclosure. A semiconductor device A5 of the present embodiment is different from the above embodiments in the configurations of the first leads 4 and the fourth leads 7.

In the present embodiment, the first lengths L1 of the first leads 4 are all equal. The lengths Lc1 of the corner leads 8 are longer than the first lengths L1 of the first leads 4. Similarly, the fourth lengths L4 of the fourth leads 7 are all equal. The lengths Lc1 of the corner leads 8 are longer than the fourth lengths L4 of the fourth leads 7.

The present embodiment can also suppress excessive stress on the conductive bonding members used for mounting. As can be understood from the present embodiment, the relationships between the first lengths L1 of the first leads 4, the fourth lengths L4 of the fourth leads 7, the second lengths L2 of the second leads 5, and the third lengths L3 of the third leads 6 are not limited in any way.

The semiconductor device of the present disclosure is not limited to the embodiments and the variations described above. Various design changes can be made to the specific configurations of the elements of the semiconductor device according to the present disclosure.

The present disclosure includes the embodiments described in the following clauses.

### Clause 1A.

A semiconductor device comprising:
a semiconductor element;
a plurality of leads; and
a sealing resin covering the semiconductor element and at least a part of each of the plurality of leads,
wherein the sealing resin includes a resin reverse surface facing in a thickness direction of the semiconductor element, a first resin side surface along a first direction perpendicular to the thickness direction, and a second resin side surface and a third resin side surface along a second direction perpendicular to the thickness direction and the first direction,
the plurality of leads include a plurality of first leads aligned in the first direction,
each of the plurality of first leads includes a first mounting surface exposed from the resin reverse surface,
the first mounting surface reaches the first resin side surface, and is spaced apart from the second resin side surface and the third resin side surface, and
first lengths, which are lengths of the first mounting surfaces of the plurality of first leads in the second direction, are such that the first length of each of the first leads located at opposite ends in the first direction is longer than the first length of any of a rest of the first leads.

### Clause 2A.

The semiconductor device according to clause 1A, wherein the first lengths of the plurality of first leads are such that the first length of a first lead located more outward in the first direction is longer than the first length of a first lead located closer to a center in the first direction.

### Clause 3A.

The semiconductor device according to clause 1A or 2A, wherein the sealing resin has a rectangular shape as viewed in the thickness direction.

### Clause 4A.

The semiconductor device according to any of clauses 1A to 3A, wherein each of the plurality of first leads includes a first end surface exposed from the first resin side surface.

### Clause 5A.

The semiconductor device according to any of clauses 1A to 4A, wherein the first mounting surface has a shape that extends in the second direction.

### Clause 6A.

The semiconductor device according to any of clauses 1A to 5A, wherein a length of the first resin side surface in the first direction is longer than a length of each of the second resin side surface and the third resin side surface in the second direction.

### Clause 7A.

The semiconductor device according to any of clauses 1A to 5A, wherein a length of the first resin side surface in the first direction is shorter than a length of each of the second resin side surface and the third resin side surface in the second direction.

### Clause 8A.

The semiconductor device according to any of clauses 1A to 5A, wherein a length of the first resin side surface in the first direction is equal to a length of each of the second resin side surface and the third resin side surface in the second direction.

### Clause 9A.

The semiconductor device according to any of clauses 1A to 8A, wherein each of the first leads includes a first thick portion including the first mounting surface, and a first thin portion spaced apart from the resin reverse surface in the thickness direction.

### Clause 10A.

The semiconductor device according to any of clauses 1A to 9A, wherein the sealing resin further includes a fourth resin side surface facing away from the first resin side surface in the second direction, and
the plurality of leads further include a plurality of second leads aligned in the second direction along the second resin side surface, a plurality of third leads aligned in the second direction along the third resin side surface, and a plurality of fourth leads aligned in the first direction along the fourth resin side surface.

### Clause 11A.

The semiconductor device according to clause 10A, wherein each of the plurality of second leads includes a second mounting surface exposed from the resin reverse surface,
the second mounting surface reaches the second resin side surface, and is spaced apart from the first resin side surface and the fourth resin side surface,
each of the plurality of third leads includes a third mounting surface exposed from the resin reverse surface,
the third mounting surface reaches the third resin side surface, and is spaced apart from the first resin side surface and the fourth resin side surface,
each of the plurality of fourth leads includes a fourth mounting surface exposed from the resin reverse surface, and
the fourth mounting surface reaches the fourth resin side surface, and is spaced apart from the second resin side surface and the third resin side surface.

### Clause 12A.

The semiconductor device according to clause 11A, fourth lengths, which are lengths of the fourth mounting surfaces of the plurality of fourth leads in the second direction, are such that the fourth length of each of the fourth leads located at opposite ends in the first direction is longer than the fourth length of any of a rest of the fourth leads.

### Clause 13A.

The semiconductor device according to clause 12A, wherein the fourth lengths of the plurality of fourth leads are such that the fourth length of a fourth lead located more outward in the first direction is longer than the fourth length of a fourth lead located closer to a center in the first direction.

### Clause 14A.

The semiconductor device according to any of clauses 11A to 13A, wherein second lengths, which are lengths of the second mounting surfaces of the plurality of second leads in the first direction, and third lengths, which are lengths of the third mounting surfaces of the plurality of third leads in the first direction, are shorter than the first lengths of the first leads located at opposite ends in the first direction.

### Clause 15A.

The semiconductor device according to any of clauses 11A to 13A, wherein second lengths, which are lengths of the second mounting surfaces of the plurality of second leads in the first direction, are such that the second length of each of the second leads located at opposite ends in the second direction is longer than the second length of any of a rest of the second leads, and
third lengths, which are lengths of the third mounting surfaces of the plurality of third leads in the first direction, are such that the third length of each of the third leads located at opposite ends in the second direction is longer than the third length of any of a rest of the third leads.

### Clause 16A.

The semiconductor device according to any of clauses 11A to 15A, wherein the plurality of leads further include a corner lead including a corner mounting surface that is located outside the first mounting surfaces of the plurality of first leads in the first direction, and that is exposed from the resin reverse surface,
the corner mounting surface includes a first portion and a second portion, the first portion reaching the first resin side surface and being spaced apart from the second resin side surface and the third resin side surface, the second portion reaching the second resin side surface or the third resin side surface and being spaced apart from the first resin side surface and the fourth resin side surface, and the first portion and the second portion are connected to each other.

### Clause 17A.

The semiconductor device according to clause 16A, wherein a length of the corner mounting surface in the second direction is longer than the first length of each of the first leads located at opposite ends in the first direction.

The present disclosure further includes the embodiments described in the following clauses.

### Clause 1B.

A semiconductor device comprising:
a semiconductor element;
a plurality of leads; and
a sealing resin covering the semiconductor element and at least a part of each of the plurality of leads,
wherein the sealing resin includes a resin reverse surface facing in a thickness direction of the semiconductor element, a first resin side surface and a fourth resin side surface along a first direction perpendicular to the thickness direction, and a second resin side surface and a third resin side surface along a second direction perpendicular to the thickness direction and the first direction,
the plurality of leads include a plurality of first leads, a plurality of fourth leads, and a corner lead,
the plurality of first leads are aligned in the first direction along the first resin side surface,
the plurality of fourth leads are aligned in the first direction along the fourth resin side surface,
each of the plurality of first leads includes a first mounting surface exposed from the resin reverse surface,
each of the plurality of fourth leads includes a fourth mounting surface exposed from the resin reverse surface,
the corner lead includes a corner mounting surface that is located outside the first mounting surfaces of the plurality of first leads or the fourth mounting surfaces of the plurality of fourth leads in the first direction, and that is exposed from the resin reverse surface,
the corner mounting surface includes a first portion and a second portion, the first portion reaching the first resin side surface or the fourth resin side surface and being spaced apart from the second resin side surface and the third resin side surface, the second portion reaching the second resin side surface or the third resin side surface and being spaced apart from the first resin side surface and the fourth resin side surface, and
the first portion and the second portion are connected to each other.

### Clause 2B.

The semiconductor device according to clause 1B, wherein the sealing resin has a rectangular shape as viewed in the thickness direction.

### Clause 3B.

The semiconductor device according to clause 1B or 2B, wherein an array pitch between the first mounting surfaces of the plurality of first leads is equal to an array pitch between the first mounting surface of a first lead located outermost in the first direction out of the plurality of first leads and the first portion.

### Clause 4B.

The semiconductor device according to any of clauses 1B to 3B, wherein a width of the first mounting surface of each of the plurality of first leads in the first direction is equal to a width of the first portion in the first direction.

### Clause 5B.

The semiconductor device according to any of clauses 1B to 4B, wherein a length of the corner mounting surface in the second direction is longer than a length of the first mounting surface of each of the plurality of first leads in the second direction.

### Clause 6B.

The semiconductor device according to any of clauses 1B to 5B, wherein a length of the first portion in the second direction is longer than a length of the second portion in the first direction.

### Clause 7B.

The semiconductor device according to any of clauses 1B to 5B, wherein a length of the first portion in the second direction is shorter than a length of the second portion in the first direction.

### Clause 8B.

The semiconductor device according to any of clauses 1B to 5B, wherein a length of the first portion in the second direction is equal to a length of the second portion in the first direction.

### Clause 9B.

The semiconductor device according to any of clauses 1B to 8B, wherein the corner lead includes a first corner end surface exposed from the first resin side surface, and a second corner end surface exposed from the second resin side surface or the third resin side surface.

### Clause 10B.

The semiconductor device according to any of clauses 1B to 9B, wherein a length of the first resin side surface in the first direction is longer than a length of each of the second resin side surface and the third resin side surface in the second direction.

### Clause 11B.

The semiconductor device according to any of clauses 1B to 9B, wherein a length of the first resin side surface in the first direction is shorter than a length of each of the second resin side surface and the third resin side surface in the second direction.

### Clause 12B.

The semiconductor device according to any of clauses 1B to 9B, wherein a length of the first resin side surface in the first direction is equal to a length of each of the second resin side surface and the third resin side surface in the second direction.

### Clause 13B.

The semiconductor device according to any of clauses 1B to 12B, wherein the corner lead includes a corner thick portion including the corner mounting surface, and a corner thin portion spaced apart from the resin reverse surface in the thickness direction.

### Clause 14B.

The semiconductor device according to any of clauses 1B to 13B, wherein the plurality of leads further include a plurality of second leads aligned in the second direction along the second resin side surface, a plurality of third leads aligned in the second direction along the third resin side surface, and a plurality of fourth leads aligned in the first direction along the fourth resin side surface.

### Clause 15B.

The semiconductor device according to clause 14B, wherein each of the plurality of second leads includes a second mounting surface exposed from the resin reverse surface,
the second mounting surface reaches the second resin side surface, and is spaced apart from the first resin side surface and the fourth resin side surface,
each of the plurality of third leads includes a third mounting surface exposed from the resin reverse surface,
the third mounting surface reaches the third resin side surface, and is spaced apart from the first resin side surface and the fourth resin side surface, and
the fourth mounting surface reaches the fourth resin side surface, and is spaced apart from the second resin side surface and the third resin side surface.

### Clause 16B.

The semiconductor device according to clause 15B, wherein an array pitch between the second mounting surfaces of the plurality of second leads is equal to an array pitch between the second mounting surface of a second lead located outermost in the second direction out of the plurality of second leads and the second portion.

### Clause 17B.

The semiconductor device according to clause 15B or 16B, wherein a width of the second mounting surface of each of the plurality of second leads in the second direction is equal to a width of the second portion in the second direction.

### REFERENCE NUMERALS

A1, A11, A12, A13, A2, A3, A4, A5: Semiconductor device
1: Semiconductor element
2: Sealing resin
4: First lead
5: Second lead
6: Third lead
7: Fourth lead
8: Corner lead
9: Center lead
21: Resin obverse surface
22: Resin reverse surface
23: First resin side surface
24: Second resin side surface
25: Third resin side surface
26: Fourth resin side surface
41: First thick portion
42: First thin portion
43: First mounting surface
44: First end surface
51: Second thick portion
52: Second thin portion
53: Second mounting surface
54: Second end surface
61: Third thick portion
62: Third thin portion
63: Third mounting surface
64: Third end surface
71: Fourth thick portion
72: Fourth thin portion
73: Fourth mounting surface
74: Fourth end surface
81: Corner thick portion
82: Corner thin portion
83: Corner mounting surface
831: First portion
832: Second portion
833: Third portion
841: First corner end surface
842: Second corner end surface
911, 912, 913: Center thick portion
921, 922: Center thin portion
931, 932, 933: Center mounting surface
941, 942: Center end surface
P1, P2, P3, P4, Pc1, Pc2, Pc3, Pc4: Array pitch
x: First direction
y: Second direction
z: Thickness direction

1. A semiconductor device comprising:
a semiconductor element;
a plurality of leads; and
a sealing resin covering the semiconductor element and at least a part of each of the plurality of leads,
wherein the sealing resin includes a resin reverse surface facing in a thickness direction of the semiconductor element, a first resin side surface along a first direction perpendicular to the thickness direction, and a second resin side surface and a third resin side surface along a second direction perpendicular to the thickness direction and the first direction,
the plurality of leads include a plurality of first leads aligned in the first direction,
each of the plurality of first leads includes a first mounting surface exposed from the resin reverse surface,
the first mounting surface reaches the first resin side surface, and is spaced apart from the second resin side surface and the third resin side surface, and
first lengths, which are lengths of the first mounting surfaces of the plurality of first leads in the second direction, are such that the first length of each of the first leads located at opposite ends in the first direction is longer than the first length of any of a rest of the first leads.

2. The semiconductor device according to claim 1, wherein the first lengths of the plurality of first leads are such that the first length of a first lead located more outward in the first direction is longer than the first length of a first lead located closer to a center in the first direction.

3. The semiconductor device according to claim 1, wherein the sealing resin has a rectangular shape as viewed in the thickness direction.

4. The semiconductor device according to claim 1, wherein each of the plurality of first leads includes a first end surface exposed from the first resin side surface.

5. The semiconductor device according to claim 1, wherein the first mounting surface has a shape that extends in the second direction.

6. The semiconductor device according to claim 1, wherein a length of the first resin side surface in the first direction is longer than a length of each of the second resin side surface and the third resin side surface in the second direction.

7. The semiconductor device according to claim 1, wherein a length of the first resin side surface in the first direction is shorter than a length of each of the second resin side surface and the third resin side surface in the second direction.

8. The semiconductor device according to claim 1, wherein a length of the first resin side surface in the first direction is equal to a length of each of the second resin side surface and the third resin side surface in the second direction.

9. The semiconductor device according to claim 1, wherein each of the first leads includes a first thick portion including the first mounting surface, and a first thin portion spaced apart from the resin reverse surface in the thickness direction.

10. The semiconductor device according to claim 1, wherein the sealing resin further includes a fourth resin side surface facing away from the first resin side surface in the second direction, and
the plurality of leads further include a plurality of second leads aligned in the second direction along the second resin side surface, a plurality of third leads aligned in the second direction along the third resin side surface, and a plurality of fourth leads aligned in the first direction along the fourth resin side surface.

11. The semiconductor device according to claim 10, wherein each of the plurality of second leads includes a second mounting surface exposed from the resin reverse surface,
the second mounting surface reaches the second resin side surface, and is spaced apart from the first resin side surface and the fourth resin side surface,
each of the plurality of third leads includes a third mounting surface exposed from the resin reverse surface,
the third mounting surface reaches the third resin side surface, and is spaced apart from the first resin side surface and the fourth resin side surface,
each of the plurality of fourth leads includes a fourth mounting surface exposed from the resin reverse surface, and
the fourth mounting surface reaches the fourth resin side surface, and is spaced apart from the second resin side surface and the third resin side surface.

12. The semiconductor device according to claim 11, fourth lengths, which are lengths of the fourth mounting surfaces of the plurality of fourth leads in the second direction, are such that the fourth length of each of the fourth leads located at opposite ends in the first direction is longer than the fourth length of any of a rest of the fourth leads.

13. The semiconductor device according to claim 12, wherein the fourth lengths of the plurality of fourth leads are such that the fourth length of a fourth lead located more outward in the first direction is longer than the fourth length of a fourth lead located closer to a center in the first direction.

14. The semiconductor device according to claim 11, wherein second lengths, which are lengths of the second mounting surfaces of the plurality of second leads in the first direction, and third lengths, which are lengths of the third mounting surfaces of the plurality of third leads in the first direction, are shorter than the first lengths of the first leads located at opposite ends in the first direction.

15. The semiconductor device according to claim 11, wherein second lengths, which are lengths of the second mounting surfaces of the plurality of second leads in the first direction, are such that the second length of each of the second leads located at opposite ends in the second direction is longer than the second length of any of a rest of the second leads, and
third lengths, which are lengths of the third mounting surfaces of the plurality of third leads in the first direction, are such that the third length of each of the third leads located at opposite ends in the second direction is longer than the third length of any of a rest of the third leads.

16. The semiconductor device according to claim 11, wherein the plurality of leads further include a corner lead including a corner mounting surface that is located outside the first mounting surfaces of the plurality of first leads in the first direction, and that is exposed from the resin reverse surface,
the corner mounting surface includes a first portion and a second portion, the first portion reaching the first resin side surface and being spaced apart from the second resin side surface and the third resin side surface, the second portion reaching the second resin side surface or the third resin side surface and being spaced apart from the first resin side surface and the fourth resin side surface, and
the first portion and the second portion are connected to each other.

17. The semiconductor device according to claim 16, wherein a length of the corner mounting surface in the second direction is longer than the first length of each of the first leads located at opposite ends in the first direction.
